(19) United States
(12) Patent Application Publication
(10) Pub. No.: US 2019/0004576 A1
(43) Pub. Date: Jan. 3, 2019

(54) ADAPTIVE COOLING HEAT SPREADER

(71) Applicant: Microsoft Technology Licensing, LLC, Redmond, WA (US)

(72) Inventors: Chau Van Ho, DesMoines, WA (US); David Otto Whitt, III, Redmond, WA (US); Andrew Douglas Delano, Woodinville, WA (US); Bharath Nagendran, Redmond, WA (US)

(21) Appl. No.: 15/639,773

(22) Filed: Jun. 30, 2017

(51) Int. Cl. G06F 1/20; H05K 7/20; G05B 15/02

(52) U.S. Cl. CPC G06F 1/206; G05B 15/02; H05K 7/2039; G06F 1/203

(57) ABSTRACT

Computing devices, thermal management devices, and corresponding use methods are described herein. A computing device includes a housing, an electronic component supported by the housing, and a heat spreader physically connected to the electronic component. The heat spreader includes an adjustable part that is adjustable between a first state and a second state. Heat generated by the electronic component flows through the adjustable part when the adjustable part is in the first state, and the adjustable part is operable to redirect at least a portion of the heat when the adjustable part is in the second state.

### BRIEF DESCRIPTION OF THE DRAWINGS

For a more complete understanding of the disclosure, reference is made to the following detailed description and accompanying drawing figures, in which like reference numerals may be used to identify like elements in the figures.

FIG. 1 depicts a top view of a computing device including an example of a thermal management system.

FIG. 2 depicts a bottom view of an example of a thermal management device.

FIG. 3 depicts a side view of a computing device including an example of the thermal management device of FIG. 2.

FIG. 4 shows a detailed first side view of an example of an adjustable part of the thermal management device of FIG. 2 in an activated state.

FIG. 5 shows a detailed second side view of an example of an adjustable part of the thermal management device of FIG. 2 in a deactivated state.

FIG. 6 shows a top view of another example of a thermal management device.

FIG. 7 shows a side view of a portion of the thermal management device of FIG. 6.

FIG. 8 is a flow diagram of a method for cooling an electronic device in accordance with one example.

FIG. 9 is a block diagram of a computing environment in accordance with one example for implementation of the disclosed methods or one or more electronic devices.

While the disclosed devices, systems, and methods are representative of embodiments in various forms, specific embodiments are illustrated in the drawings (and are hereafter described), with the understanding that the disclosure is intended to be illustrative, and is not intended to limit the claim scope to the specific embodiments described and illustrated herein

### DETAILED DESCRIPTION

Current microprocessor design trends include designs having an increase in power, a decrease in size, and an increase in speed. This results in higher power in a smaller, faster microprocessor. Another trend is towards lightweight and compact electronic devices. As microprocessors become lighter, smaller, and more powerful, the microprocessors also generate more heat in a smaller space, making thermal management a greater concern than before.

The purpose of thermal management is to maintain the temperature of a device within a moderate range. During operation, electronic devices dissipate power as heat that is to be removed from the device. Otherwise, the electronic device will get hotter and hotter until the electronic device fails, reducing service life of the electronic device. Short of failure, electronic devices run slowly and dissipate power poorly at high temperatures.

As devices get smaller (e.g., thinner), thermal management becomes more of an issue. Depending on the thickness of the device, there may not be sufficient room within the device for active thermal management components such as, for example, fans. Also, as mobile devices (e.g., phones and tablets) replace larger laptop and desktop computers, the microprocessors may sometimes be tasked with running a full desktop environment and may thus generate more heat.

Thermal management systems of the prior art may use sensors to track temperatures at outer surfaces of the computing device and throttle one or more of the components when a tracked temperature approaches a temperature limit. In other words, touch temperatures may limit processing speeds for the computing device. The throttling of the one or more components of the computing device leads to decreased performance for the computing device.

Disclosed herein are apparatuses, systems, and methods for adaptive thermal management for an electronic device and optimized power to electronic components within the electronic device. The adaptive thermal management for the electronic device may be provided by an adjustable part of a thermal management device such as, for example, a heat spreader. Heat generated within the electronic device flows through the adjustable part of the thermal management device when the adjustable part is activated, and the adjustable part redirects a portion of the heat when the adjustable part is deactivated. In other words, the adjustable part acts as a thermal conductor when the adjustable part is activated, and acts as a thermal insulator when the adjustable part is deactivated.

The adjustable part may be controlled based on outputs from one or more sensors that determine whether a user is in physical contact with the electronic device. When the one or more sensors determine the user is in physical contact with the electronic device, power to an electronic component is controlled based at least on a temperature at an outer surface of the electronic component, as determined by a first temperature sensor, and a temperature at the electronic component, as determined by a second temperature sensor. When the one or more sensors determine the user is not in physical contact with the electronic device, power to the electronic component is controlled based on the temperature at the electronic component, but not the temperature at the outer surface of the electronic component. The electronic device may thus be allowed to operate at a higher power when the user is not in physical contact with the electronic device.

As an example, the adaptive thermal management for an electronic device may be implemented within a computing device including a housing, an electronic component supported by the housing, and a heat spreader physically connected to the electronic component. The heat spreader includes an adjustable part that is adjustable between a first state and a second state. Heat generated by the electronic component flows through the adjustable part when the adjustable part is in the first state, and the adjustable part is operable to redirect at least a portion of the heat when the adjustable part is in the second state.

Heat dissipation apparatuses, systems, and methods of the present embodiments have several potential end-uses or applications, including any electronic device having a passive or an active cooling component (e.g., fan). For example, the heat dissipation apparatus may be incorporated into personal computers, server computers, tablet or other handheld computing devices, laptop or mobile computers, communications devices such as mobile phones, multiprocessor systems, microprocessor-based systems, set top boxes, programmable consumer electronics, network PCs, minicomputers, mainframe computers, displays, or audio or video media players. In certain examples, the heat dissipation apparatus may be incorporated within a wearable electronic device, where the device may be worn on or attached to a person's body or clothing. The wearable device may be attached to a person's shirt or jacket; worn on a person's wrist, ankle, waist, or head; or worn over their eyes or ears. Such wearable devices may include a watch, heart-rate monitor, activity tracker, or head-mounted display.

Using one or more of these features described in greater detail below, adaptive thermal management and optimized power to electronic components may be provided for the electronic device. With the adaptive thermal management and optimized power features, a more powerful microprocessor may be installed for the electronic device, a thinner electronic device may be designed, a higher processing speed may be provided, or a combination thereof may be provided when compared to a similar electronic device without these features. In other words, the features described herein may provide improved thermal management and/or optimized power for an electronic device such as a mobile phone, tablet computer, or laptop computer.

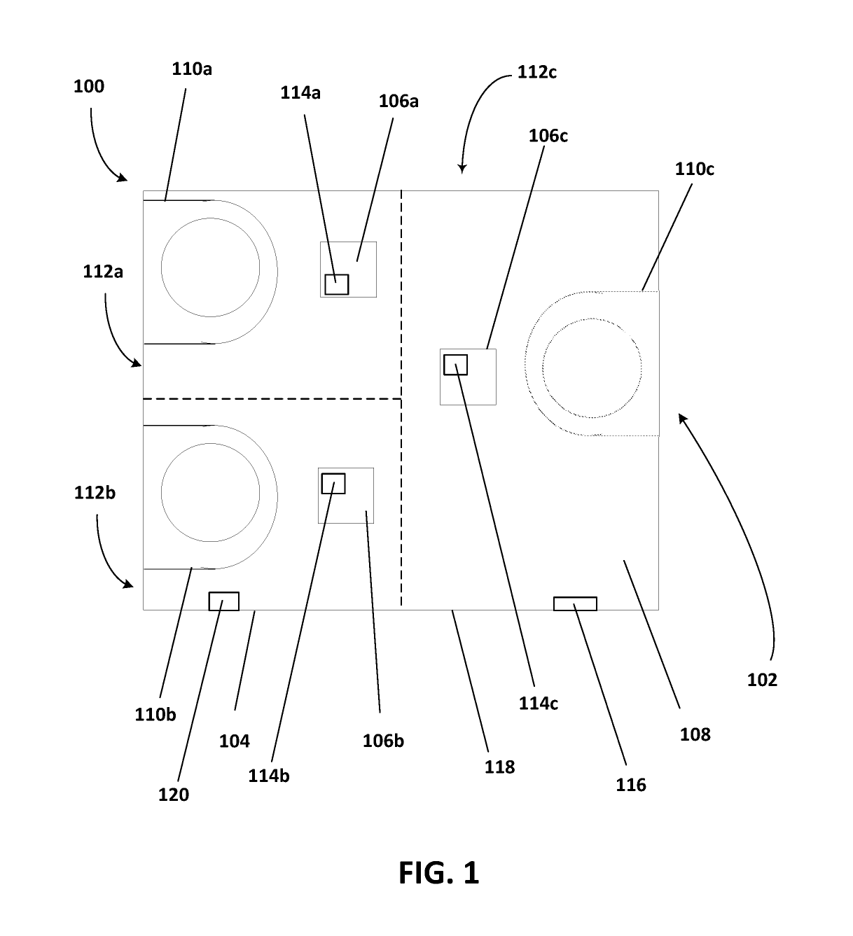

FIG. 1 shows a top view of a computing device 100 including an example of a thermal management system 102. The computing device 100 may be any number of computing devices including, for example, a personal computer, a server computer, a tablet or other handheld computing device, a laptop or mobile computer, a communications device such as a mobile phone, a multiprocessor system, a microprocessor-based system, a set top box, a programmable consumer electronic device, a network PC, a minicomputer, a mainframe computer, or an audio and/or video media player.

The computing device 100 includes a housing 104 that supports at least the thermal management system 102 and one or more heat generating components 106. The one or more heat generating components 106 may be any number of electrically powered devices including, for example, a processor, memory, a power supply, a graphics card, a hard drive, or another electrically powered device. The one or more heat generating components 106 may be supported by the housing 104 via, for example, a printed circuit board (PCB) 108 attached to and/or supported by the housing 104. The one or more heat generating components 106 are in communication with each other and/or other electrical devices or components (e.g., fans) of the computing device 100 via the PCB 108, for example. The computing device 100 may include a number of components not shown in FIG. 1 (e.g., a hard drive, a power supply, connectors).

Three heat generating components 106 (e.g., first heat generating component 106a, second heat generating component 106b, and third heat generating component 106c) are shown in the example of FIG. 1. More or fewer heat generating components 106 may be included in the computing device. In one example, the heat generating component 106a is a processor, the heat generating component 106b is a graphics card, and the heat generating component 106c is a memory. In other examples, one or more of the heat generating components 106a, 106b, and 106c represent different components within the computing device 100 (e.g., a hard drive, a power supply, or another processor).

The thermal management system 102 may include one or more fans 110 to actively cool the one or more heat generating components 106, respectively, moving heat out of the computing device 100 via vents in the housing 104 of the computing device 100. The one or more fans 110 may be any number of different types of fans including, for example, an axial-flow fan, a centrifugal fan, a crossflow fan, or another type of fan. The one or more fans 110 may rotate on any number of types of bearings including, for example, sleeve bearings, rifle bearings, ball bearings, fluid bearings, magnetic bearings, or another type of bearing. The one or more fans 110 may be sized and may rotate at a speed based on the heat generating component 106 to be cooled (e.g., based on the heat generated by the heat generating component 106 to be cooled). Each of the one or more fans 110 may be the same type of fan, or different types of fans may be used.

In the example shown in FIG. 1, the thermal management system 102 includes three fans 110 (e.g., first fan 110a, second fan 110b, and third fan 110c) to cool the three heat generating components 106a, 106b, and 106c, respectively. The thermal management system 102 may include more or fewer fans 110. For example, in one embodiment, the thermal management system 102 includes zero fans.

The computing device 100 is divided into zones 112. The computing device 100 shown in the example of FIG. 1 includes three zones 112 (e.g., first zone 112a, second zone 112b, and third zone 112c). In other examples, the computing device 100 includes more, fewer, or different zones. In the example shown in FIG. 1, the first zone 112a includes the first heat generating component 106a, the second zone 112b includes the second heat generating component 106b, and the third zone 112c includes the third heat generating component 106c. In other embodiments, more than one heat generating component may be included within a zone. The computing device 100 may be divided into the zones 112 based on locations of heat generating components 106 to be cooled, locations of fans 110, locations of peak temperatures during operation of the computing device 100, and/or based on other information. The assignment of the zones 112 may be fixed when the computing device 100 is manufactured, or the zones 112 may vary based on operating conditions (e.g., temperatures) within the computing device 100.

The thermal management system 102 also includes one or more sensors 114 that monitor temperatures within the zones 112, respectively. The one or more sensors 114 may be any number of different types of temperature sensors including, for example, a thermocouple, a resistance temperature detector (RTD) (e.g., a resistance wire RTD or a thermistor), or another type of temperature sensor. All of the one or more sensors 114 may be the same type of sensor, or different types of sensors may be used within the computing device 100.

As shown in the example of FIG. 1, the thermal management system 102 may include three sensors 114 (e.g., a first sensor 114a, a second sensor 114b, and a third sensor 114c) to track temperatures within the first zone 112a, the second zone 112b, and the third zone 112c, respectively. The first sensor 114a monitors a temperature within the first zone 112a, the second sensor 114b monitors a temperature within the second zone 112b, and the third sensor 114c monitors a temperature within the third zone 112c. For example, the first sensor 114a monitors an operating temperature of the first heat generating component 106a, the second sensor 114b monitors an operating temperature of the second heat generating component 106b, and the third sensor 114c monitors an operating temperature of the third heat generating component 106c. The first sensor 114a, the second sensor 114b, and the third sensor 114c are positioned on or adjacent to the first heat generating component 106a, the second heat generating component 106b, and the third heat generating component 106c, respectively. In one example, a sensor 114 monitors a temperature at a position within the computing device 100 not at or adjacent to one of the heat generating components. For example, the sensor 114 may monitor a temperature of a component of the thermal management system 102 (e.g., at a position on a phase change device such as a heat pipe). In one embodiment, at least one of the zones 112 includes a plurality of sensors 114. The plurality of sensors 114 in the one zone 112 respectively monitor the temperatures of a plurality of components and/or positions within the one zone 112.

The thermal management system 102 also includes one or more sensors 116 that monitor temperatures on an outer surface 118 of the housing 104 of the computing device 100. The one or more sensors 116 may be disposed on the outer surface 118 of the housing 104 and/or may be disposed within the housing 104 of the computing device 100. In one embodiment, a plurality of sensors 116 are disposed at the outer surface 118 of the housing 104 in positions a user is expected to contact. The one or more sensors 116 may be any number of different types of temperature sensors including, for example, a thermocouple, a resistance temperature detector (RTD) (e.g., a resistance wire RTD or a thermistor), or another type of temperature sensor. All of the one or more sensors 116 may be the same type of sensor, or different types of sensors may be used within the computing device 100.

The computing device 100 also includes one or more sensors 120 that monitor physical contact between a user (e.g., a hand of the user) of the computing device 100 and the computing device 100. The one or more sensors 120 may be disposed on the outer surface 118 of the housing 104 and/or may be disposed within the housing 104 of the computing device 100. In one embodiment, a plurality of sensors 120 are disposed at the outer surface 118 of the housing 104 in positions the user is expected to contact. The one or more sensors 120 may be any number of different types of sensors including, for example, a capacitive sensor or another type of contact sensor. All of the one or more sensors 120 may be the same type of sensor, or different types of sensors may be used within the computing device 100. In one example, the one or more sensors 120 include a plurality of sensors 120 arranged in a grid operable to identify physical contact between the user of the computing device and one or more external surfaces of the computing device 100.

All of the sensors 114, 116, 120 within the computing device 100 provide live closed-loop feedback to the thermal management system 102. For example, the thermal management system 102 includes a processor (e.g., one of the heat generating components 106 or another processor within or outside the computing device 100). Thermal management systems of the prior art may use sensors to track temperature and increase fan speed as soon as any component is approaching a limit. Increasing the fan speed based only on temperature limits may result in over cooling, which requires additional power than necessary and creates a noisier computing device. The processor 106a, for example, receives the live temperatures from the sensors 114a, 114b, and 114c and controls the fans 110a, 110b, and 110c based on the methods described below to avoid both under cooling, which reduces system performance and component life expectancy, and over cooling.

The thermal management system 102 may include additional, fewer, and/or different components (e.g., heat sinks and/or phase change devices) to aid in the removal of heat from the computing device 100. For example, the thermal management system 102 may include heat sinks physically attached or adjacent to a respective heat generating components 106. As discussed further below, the thermal management system 102 includes a heat spreader operable to distribute heat generated by the one or more heat generating component 106.

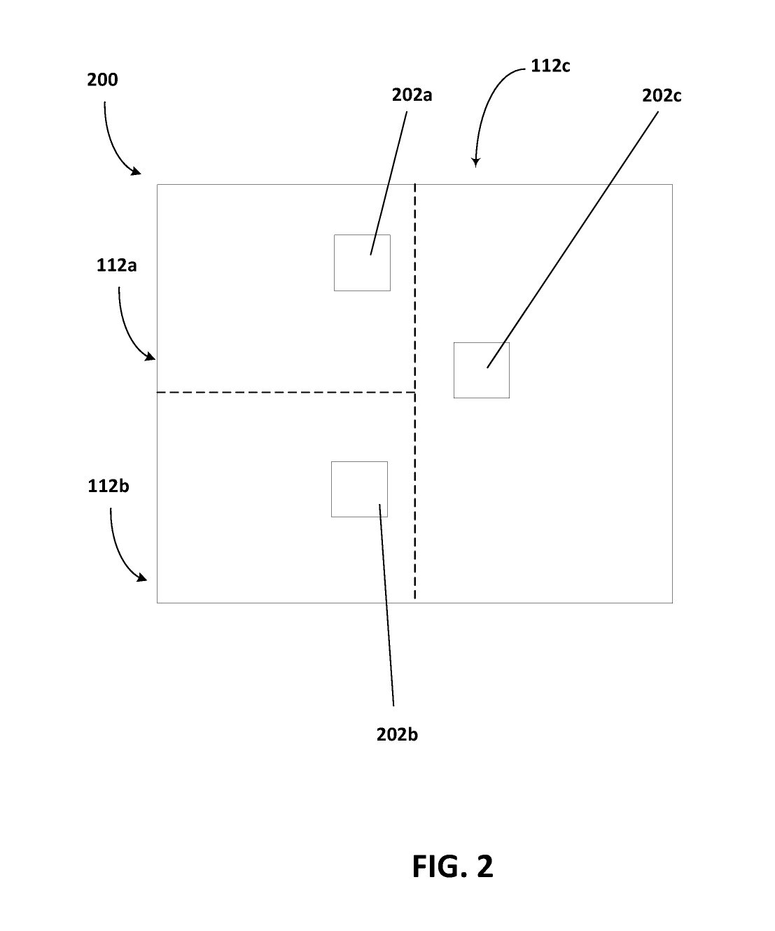

FIG. 2 depicts a bottom view of an example of a thermal management device 200 (e.g., a heat spreader). The heat spreader 200 is disposed beneath and is physically connected to the PCB 108 shown in FIG. 1. The heat spreader 200 may be any number of sizes and/or shapes. For example, the heat spreader 200 may be sized and/or shaped to match the size and/or shape of the PCB 108 and/or an internal surface of the housing 104, respectively.

The heat spreader 200 includes one or more adjustable parts 202. In the example of FIG. 2, the heat spreader 200 includes three adjustable parts 202a, 202b, and 202c that correspond to the heat generating components 106a, 106b, and 106c, respectively. In other words, the three adjustable parts 202a, 202b, and 202c correspond to hot spots on an external surface of the housing 104 generated by the heat generating components 106a, 106b, and 106c, respectively. In other examples, the heat spreader 200 may include more or fewer adjustable parts 202. For example, the heat spreader 200 may include a same number of adjustable parts 202 as the number of sensors 120 (e.g., a grid of adjustable parts 202 corresponding to the grid of sensors 120). In one example, adjustable parts 202 cover an entire side of the heat spreader 200.

The adjustable parts 202 are adjustable between a first state and a second state. In the first state, the adjustable parts 202 are in an activated state, and in the second state, the adjustable parts 202 are in a deactivated state. In the activated state, the adjustable parts 202 act as thermal conductors, and in the deactivated state, the adjustable parts 202 act as thermal insulators. In the deactivated state, the adjustable parts 202 redirect heat generated by the one or more heat generating components 106, away from the hot spots and user positions, on the outer surface 118 of the housing 104, for example.

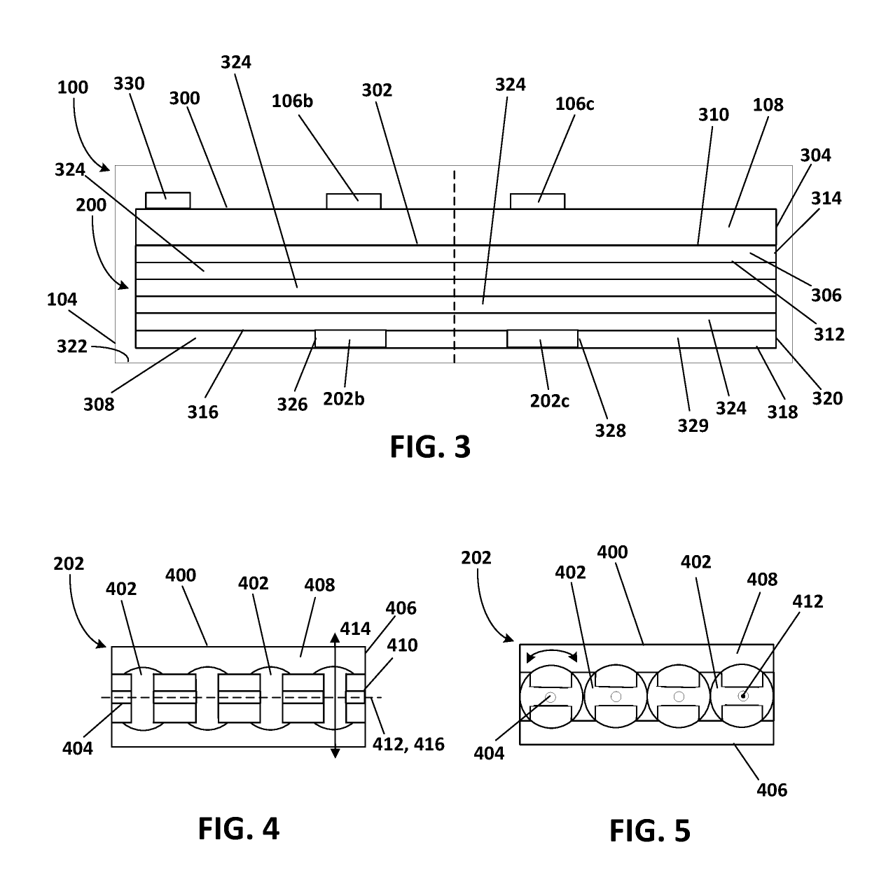

FIG. 3 depicts a side view of the thermal management device 200 of FIG. 2 positioned within the computing device 100. FIG. 3 shows two of the heat generating components 106 (e.g., the heat generating component 106b and the heat generating component 106c) supported by the PCB 108, and the thermal management device 200 is physically connected to the PCB 108.

The PCB 108 includes a first side 300, a second side 302 opposite the first side 300, and at least one third side 304 extending between the first side 300 and the second side 302. The PCB 108 is supported by the housing 104 of the computing device 100. For example, the PCB 108 is physically connected to an inner surface of the housing 104 using one or more connectors including, for example, screws, nut/bolt combinations, flanges, tabs, and/or other connectors. The example of FIG. 3 shows a single PCB 108 with components only on one side (e.g., the first side 300) of the PCB 108. In other examples, more than one PCB 108 may be supported within the housing 104 and/or components may be supported on more than one side of the PCB 108 (e.g., the first side 300 and the second side 302 of the PCB 108).

In the example shown in FIG. 3, the first side 300 of the PCB 108 supports the heat generating components 106a, 106b, and 106c. The heat generating components 106a, 106b, and 106c are physically attached to and electrically connected to the PCB 108 in any number of ways including, for example, with solder. The heat generating components 106a, 106b, and 106c may be physically attached directly to the PCB 108, or one or more intervening components may be disposed between the heat generating components 106a, 106b, and 106c and the PCB 108, respectively.

The thermal management device 200 includes a first layer 306 and a second layer 308. The first layer 306 has a first side 310, a second side 312 opposite the first side 310, and a third side 314 extending between the first side 310 and the second side 312. The first side 310 of the first layer 306 is physically connected to the second side 302 of the PCB 108. The first side 310 of the first layer 306 may be directly attached to the second side 302 of the PCB 108, or intervening layers (e.g., of a thermally conductive grease) or parts may be provided between the first side 310 of the first layer 306 and the second side 302 of the PCB 108. The first side 310 of the first layer 306 may be physically connected to the second side 302 of the PCB in any number of ways including, for example, with a thermal adhesive, one or more welds, screws, nut/bolt combinations, and/or other connectors.

In the example shown in FIG. 3, the first layer 306 is a solid piece of material. The first layer 306 may be made of any number of thermally conductive materials including, for example, copper, titanium, aluminum, graphite, graphene, or another thermally conductive material. The first layer 306 may be sized and/or shaped to match the size and/or shape of the PCB 108, respectively. In other examples, the first layer 306 is smaller or larger than the PCB 108 and/or is a different shape than the PCB 108. Other types of heat spreaders may be used as the first layer 306 of the thermal management device 200. For example, the first layer 306 may be a heat pipe, a vapor chamber, or may not be a solid piece of material but include hollow portions. Other configurations may be provided.

The second layer 308 has a first side 316, a second side 318 opposite the first side 316, and a third side 320 extending between the first side 316 and the second side 318. The second side 318 of the second layer 308 is opposite an inner surface 322 of the housing 104 of the computing device 100. In one example, the second side 318 of the second layer 308 is in physical contact with the inner surface 322 of the housing 104 of the computing device 100. The inner surface 322 of the housing 104 of the computing device 100 may be an inner surface of the back of the computing device 100.

In one example, the first side 316 of the second layer 308 is physically connected to the second side 312 of the first layer 306. In the example shown in FIG. 3, the thermal management device 200 includes a plurality of third layers 324 (e.g., four third layers), and the first side 316 of the second layer 308 is physically connected to a third layer 324 closest to the inner surface 322 of the housing 104 of the computing device 100. The first side 316 of the second layer 308 may be directly attached to the second side 312 of the first layer 306 or the third layer 324, or intervening layers (e.g., of a thermally conductive grease) or parts may be provided between the second layer 308 and the and the first layer 306 or the third layer 324. The first side 316 of the second layer 308 may be physically connected to the first layer 306 or the third layer 324 in any number of ways including, for example, with a thermal adhesive, one or more welds, screws, nut/bolt combinations, and/or other connectors.

Each third layer of the plurality of third layers 324 may be the same size, shape, and/or may be made of the same material as the first layer 306. Alternatively, one or more third layer of the plurality of third layers 324 may have a different size, shape, and/or may be made of a different material as the first layer 306. The plurality of third layers 324 may be physically connected to each other in any number of ways including, for example, with a thermal adhesive, one or more welds, screws, nut/bolt combinations, and/or other connectors.

The first layer 306 may have any number of thicknesses. For example, the first layer 306 has a thickness that matches a total thickness of the first layer 306 and the four third layers 324 shown in FIG. 3 combined, and the thermal management device 200 does not include any third layers 324. In another example, the first layer 306 is thinner and matches the thickness of each third layer of the plurality of third layers 324 included within the thermal management device 200. Other configurations may be provided.

The second layer 308 includes the adjustable parts 202. In the example shown in FIG. 3, the second layer 306 includes openings 326 extending between the first side 316 and the second side 318 of the second layer 308, and the adjustable parts 202 are positioned within the openings 326, respectively. The adjustable parts 202 may be attached to walls 328 that define the openings 326, respectively.

In the example shown in FIG. 3, a portion 329 of the second layer 308 outside of the adjustable parts 202 is a solid piece of material. The portion 329 of the second layer 308 may be made of any number of thermally conductive materials including, for example, copper, titanium, aluminum, graphite, graphene, or another thermally conductive material. An outer perimeter of the portion 329 of the second layer 308 may be sized and/or shaped to match the size and/or shape of the first layer 306, respectively. In other examples, the outer perimeter of the second 308 layer is smaller or larger than the first layer 306 and/or is a different shape than the first layer 306. Other types of heat spreaders may be used as the portion 329 of the second layer 308 of the thermal management device 200. For example, the portion 329 of the second layer 308 may be a heat pipe, a vapor chamber, or may not be a solid piece of material but include hollow portions. Other configurations may be provided.

FIG. 4 shows a detailed view of an example of an adjustable part 202 of the thermal management device 200 in the activated state (e.g., the first state), FIG. 5 shows a detailed view of an example of the adjustable part 202 of the thermal management device 200 in the deactivated state (e.g., the second state). The examples shown in FIGS. 4 and 5 may rotate between the activated state and the deactivated state in different ways. As shown in FIGS. 4 and 5, the adjustable part 202 includes a housing 400, a plurality of adjustable thermal conductors 402, and one or more shafts 404. The one or more shafts 404 are supported by the housing 400, and the plurality of adjustable thermal conductors 402 are supported by the one or more shafts 404.

The housing 400 is sized and shaped to be positioned within one of the openings 326, for example. One or more outer surfaces 406 of the housing 400 may be attached to one or more of the walls 328 that define the one opening 326. The housing 400 may be attached to the one or more walls 328 in any number of ways including, for example, with a press fit, a thermal adhesive, tabs, flanges, screws, nut/bolt combinations, other connectors, or any combination thereof.

A portion 408 of the housing 400 is made of one or more pieces of solid material. The portion 408 of the housing 400 may be made of the same material as the second layer 308 or may be made of a different material than the second layer 308. In one example, the adjustable part 202 does not include a housing, and the one or more shafts 404 are rotatably connected to the second layer 308.

The one or more shafts 404 may be rotatably connected to the housing 400 in any number of ways. For example, the one or more shafts 404 may be rotatably connected to the housing 400 via corresponding openings 410 in the housing 400. Alternatively, the one or more shafts 404 may be rotatably connected to the housing 400 via corresponding bearings in the housing 400. The one or more shafts 404 may be rotatably attached to the housing 400 in other ways. The one or more shafts 404 are made of any number of thermally conductive materials including, for example, graphite. The one or more shafts 404 may be made of the same material or a different material as the portion 408 of the housing 400 of the adjustable part 202.

The plurality of adjustable thermal conductors 402 may be any number of shapes including, for example cylindrical (e.g., a plurality of cylinders 402). The plurality of cylinders 402 are rotationally fixed relative to the one or more shafts 404 such that the plurality of cylinders 402 rotate about an axis of rotation 412, between the activated state and the deactivated state. In one example, the plurality of cylinders 402 are rotatable 90 degrees between the activated state and the deactivated state. In another example, the plurality of cylinders 402 are rotatable a full 360 degrees.

The adjustable part 202 includes any number of cylinders 402. For example, the number of cylinders 402 is set based on the size of the cylinders 402 and the size of the corresponding hotspot at the housing 104 of the computing device 100. The plurality of cylinders 402 may be any number of sizes. For example, the plurality of cylinders 402 may be nano-sized cylinders or micron-sized cylinders. Other sizes may be provided. In one example, the plurality of cylinders 402 are made of solid material. In another example, the plurality of cylinders 402 are hollow.

As shown in FIG. 4, the cylinders 402 attached to a shaft of the one or more shafts 404 may be positioned at distances away from each other. In another example, each of the cylinders 402 on the shaft 404 may abut neighboring cylinders 402. As shown in the example of FIG. 5, which illustrates four different shafts 404, each of the shafts 404 is positioned at a distance from one another such that each of the shafts 404, with respective cylinders 402, is able to rotate.

The plurality of cylinders 402 are made of any number of thermally conductive materials including, for example, graphite. Graphite is an anisotropy material having physical properties that are different when measured in different directions. In one example, a thermal conductivity is approximately 1500 W/m-K in a first direction 414, and is approximately 4 W/m-K in a second direction 416. A higher thermal conductivity provides better heat transfer from one surface to another when the surfaces are in physical contact. Each cylinder of the plurality of cylinders 402 is, for example, manufactured such that the first direction 414 aligns with a direction along the length of the cylinder 402 and the second direction 416 aligns with a direction perpendicular to the first direction 414.

When the adjustable part 202 is in the activated state, the plurality of cylinders 402 are in an orientation relative to the second layer 308, such that the first direction 414, in which the plurality of cylinders 402 have a higher thermal conductivity compared to the second direction 416, aligns with a direction of heat flow from the one or more heat generating components 106 to the second side 318 of the second layer 308. When the adjustable part 202 is in the deactivated state, the plurality of cylinders 402 are in an orientation relative to the second layer 308, such that the second direction 416, in which the plurality of cylinders 402 have a lower thermal conductivity compared to the first direction 414, aligns with the direction of heat flow from the one or more heat generating components 106 to the second side 318 of the second layer 308. In other words, in the activated state of the adjustable part 202, the plurality of cylinders 402 act as thermal conductors for heat flow between the one or more heat generating components 106 and the second side 318 of the second layer 308; in the deactivated state of the adjustable part 202, the plurality of cylinders 402 act as thermal insulators for heat flow between the one or more heat generating components 106 and the second side 318 of the second layer 308.

As shown in the example of FIG. 3, the computing device 100 may include one or more motors 330 in communication with the one or more shafts 404. The one or more motors 330 rotate the one or more shafts 404, and thus the plurality of cylinders 402, between the activated state and the deactivated state based on signals generated by contact sensors (e.g., the sensors 120) at an external surface of the housing 104 of the computing device 100. For example, the one or more motors 330 rotate the plurality of cylinders 402 into the deactivated state when the sensors 120 determine a user is in physical contact with the housing 104 of the computing device 100. The one or more motors 330 then rotate the plurality of cylinders 402 into the activated state when the sensors 120 determine the user is no longer in physical contact with the housing 104 of the computing device 100.

In another example, a device (e.g., a solenoid) internal or external to the computing device 100 generates a magnetic field operable to rotate the plurality of cylinders 402 based on signals generated by the sensors 120. For example, the computing device 100 may include one or more solenoids operable to generate a magnetic field that rotates the plurality of cylinders 402 between the activated state and the deactivated state based on signals generated by the sensors 120. As another example, the computing device 100 may be docked on a charging dock and/or a thermal dock (e.g., a dock). The dock may include a permanent magnet, and the interaction of the magnetic field generated by the permanent magnet with the plurality of cylinders 402 and the action of the user placing the computing device 100 on the dock may cause the plurality of cylinders 402 to be moved into the activated state.

Portions of the second layer 308 of the thermal management device 200 are provided, on-demand, as a thermal insulator or a thermal conductor, respectively, based on a user position (e.g., of a hand) relative to the computing device 100. For example, if the sensors 120 determine the user is holding the computing device 100, the portions of the second layer 308 of the thermal management device 200 are deactivated by rotating the plurality of cylinders 402 of the portions of the second layer 308 into an “OFF” position, and the computing device 100 is run in a normal operating condition (e.g., including touch temperature as a limiter). If the sensors 120 determine the user is no longer holding the computing device 100 (e.g., the computing device 100 is positioned on a stand, a dock, or a surface), the portions of the second layer 308 are activated by rotating the plurality of cylinders 402 of the portions of the second layer 308 into an “ON” position. Since the user is no longer in contact with the computing device 100, touch temperature is no longer a limiter for operation of the computing device 100. Additional heat may be transferred via the portions of the second layer 308 (in the “ON” position) of the thermal management device 200 and into, for example, a thermal dock, surfaces supporting the computing device 100, or other devices or surfaces. This allows a processor of the computing device 100 to run at faster speeds.

The second layer 308 of the thermal management device 200 is divided into zones that match and optimize cooling hot spots originating at the PCB 108 (e.g., the heat generating components 106 supported by the PCB 108). The computing device 100 tracks the hot spots and actively controls the plurality of cylinders 402 within the portions of the second layer 308 of the thermal management device 200 for further thermal optimization. For example, cylinders 402 within a first of the zones are controlled (e.g., deactivated) when a heat generating component 106 within the first zone is active, and cylinders 402 within a second of the zones are controlled (e.g., deactivated) when a heat generating component 106 within the second zone is active.

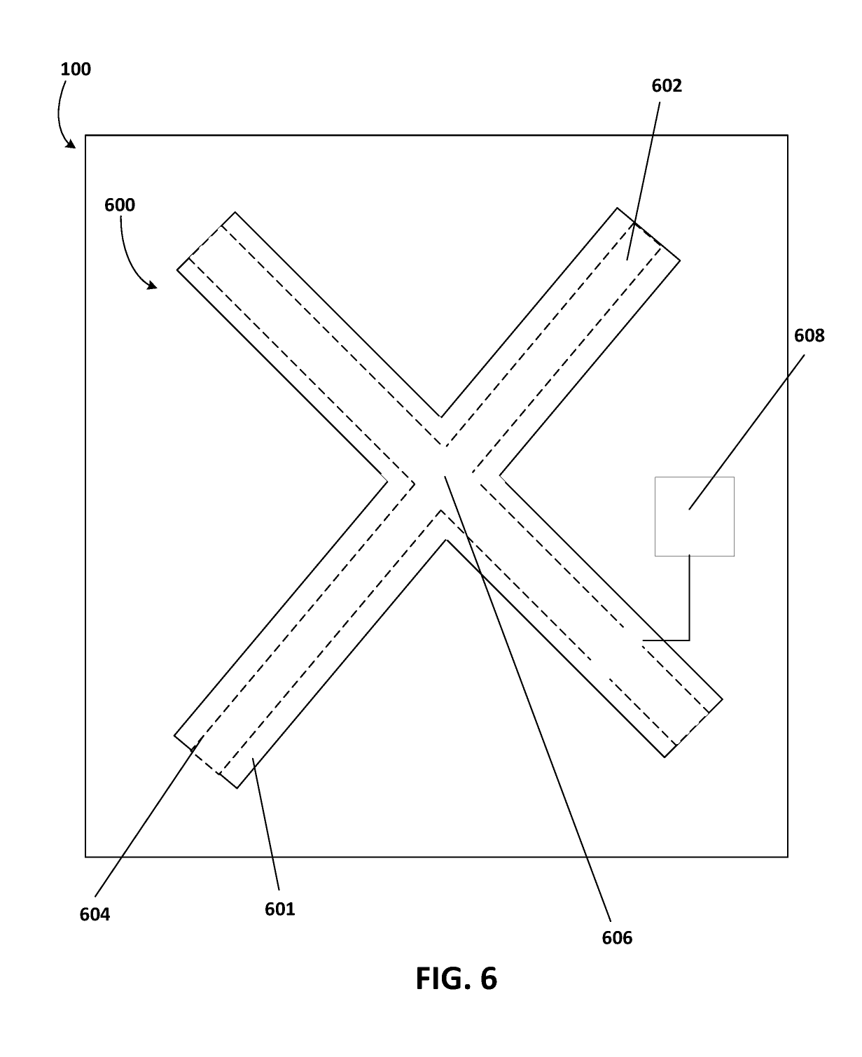

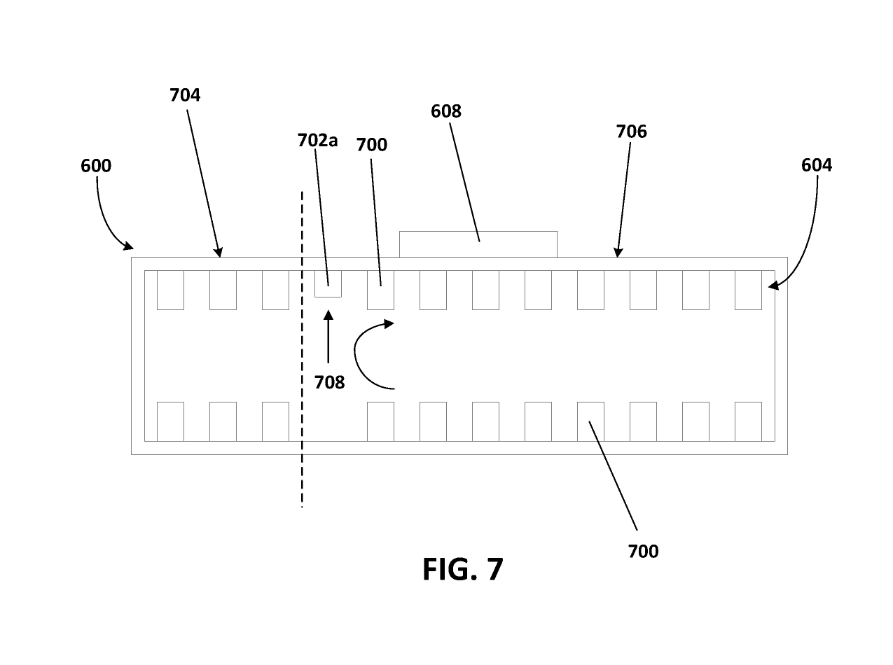

FIG. 6 shows a top view of another example of a thermal management device 600 installed within a computing device (e.g., the computing device 100). The PCB 108, for example, is positioned on a top surface 601 of the thermal management device 600, such that the thermal management device 600 abuts the second side 302 of the PCB 108. Alternatively, the first layer 306 is positioned on the top surface 601 of the thermal management device 600, such that the thermal management device 600 abuts the second side 312 of the first layer 306.

The thermal management device 600 is, for example, a phase change device such as a vapor chamber, a heat pipe, or a combination thereof. The phase change device 600 includes a vapor space 602 and capillary features 604. The vapor space 602 is a path for evaporated working fluid to travel to a condenser, and the capillary features 604 are a pathway for condensed working fluid to return to an evaporator 606 (e.g., a portion of the phase change device 600 at a heat generating component of the one or more heat generating components 106). The phase change device 600 is made of any number of thermally conductive materials including, for example, copper, aluminum, titanium, graphite, graphene, or another thermally conductive material.

The capillary features 604 may include a plurality of pins, screen wick structures, open channels, channels covered with screens, an annulus behind a screen, an artery structure, a corrugated screen, other structures, or any combination thereof. FIG. 6 illustrates an example in which the phase change device 600 is X-shaped. The phase change device 600 may be shaped differently. For example, the thermal management device may include additional legs extending from the evaporator 606 in the shape of, for example, a starburst.

At least some of the capillary features 604 may be active capillary features in that a wicking capability of the active capillary features may be controlled. For example, the active capillary features 604 may be controlled by one or more processors 608. FIG. 7 shows a side view of a portion of the phase change device 600 of FIG. 6 with a side removed. The capillary features 604 include a plurality of pins 700. At least two pins 702 of the plurality of pins 700 are active. In other examples, more or fewer pins of the plurality of pins 700 are active. For example, all pins of the plurality of pins 700 are controllable by the one or more processors 608.

In the example shown in FIG. 7, the phase change device 600 is separated into a first portion 704 and a second portion 706 by the active pins 702. The active pins 702 are movable between an activated state and a deactivated state. For example, a first of the active pins 702a is movable from the activated state to the deactivated state in a direction 708. A second of the active pins 702 (not shown) is fully retracted in the example shown in FIG. 7. The active pins 702 may be translatable or rotatable between the activated state and the deactivated state. The active pins 702 may be movable mechanically using a motor and linkages, and/or the active pins 702 may be movable using microelectromechanical (MEMS) technology. In other examples, electrowetting or electric fields may be generated at the active pins 702 to control the wicking capability of the active pins 702.

By moving the active pins 702 into the deactivated state, for example, the first portion 704 of the phase change device 600 is cut off from the second portion 706. In other words, a portion of a wicking structure of the phase change device 600 is cut off. Condensed liquid pools up in the first portion 704 and does not return to the evaporator 606 when the active pins 702 are in the deactivated state, and vapor does not travel to the first portion 704. At least the first portion 704 of the phase change device 600 eventually dries up, and the first portion 704 of the phase change device 600 is more insulating than the second portion 706 of the phase change device 600.

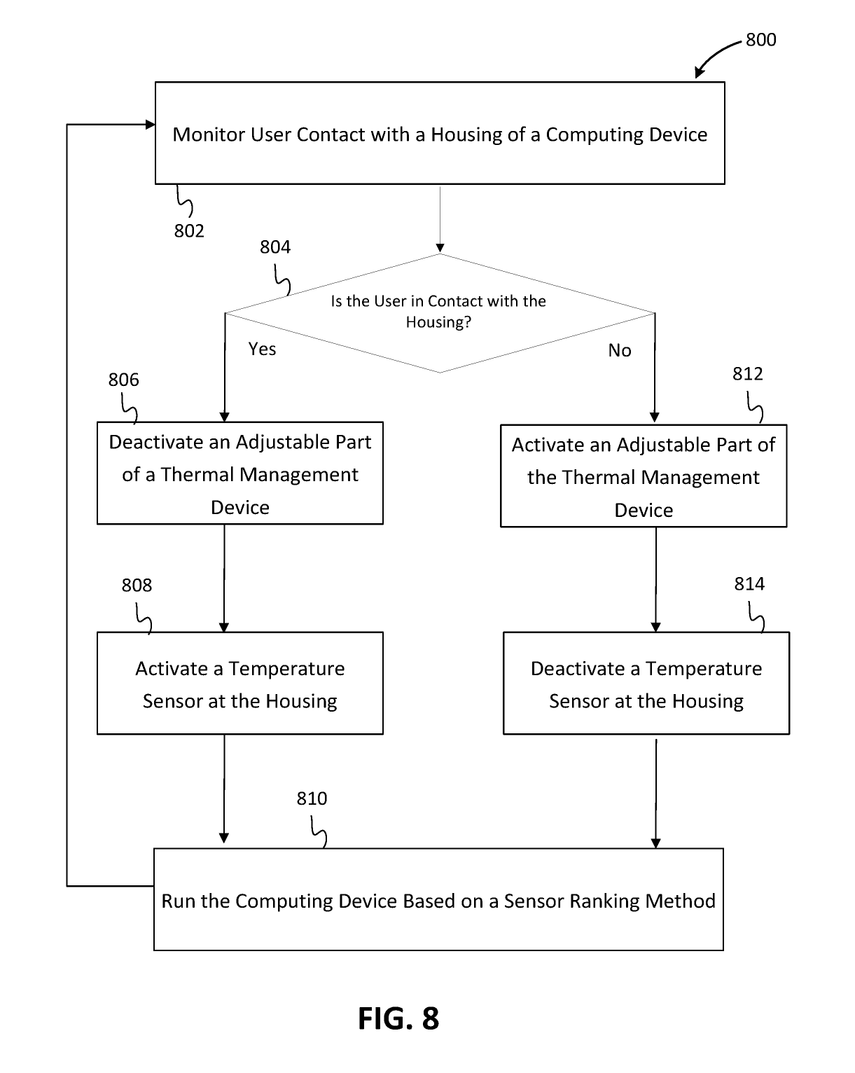

FIG. 8 shows a flowchart of one example of a method 800 for cooling an electronic device in accordance with one example. The method 800 is implemented in the order shown, but other orders may be used. Additional, different, or fewer acts may be provided. Similar methods may be used for transferring heat.

In act 802, a first sensor monitors user contact with a housing of a computing device. In one example, a plurality of first sensors monitor user contact with an external surface of the housing of the computing device. For example, first sensors may be evenly spread out over a top (e.g., a display) of the computing device and a back of the computing device (e.g., a chassis). The first sensors may be any number of different types of sensors including, for example, capacitive sensors. In one example, all of the first sensors are a first type of sensor. In another example, a first subset of the first sensors is a first type of sensor, and a second subset of the first sensors is a second type of sensor. More than two different types of sensors may be used.

The first sensor may monitor user contact with the housing of the computing device continuously. Alternatively, the first sensor may determine whether the user is in physical contact with the housing of the computing device at a predetermined interval (e.g., every 0.1 s), and a processor of the computing device may execute the method 800 every predetermined interval.

In act 804, a processor determines whether the user is in contact with the housing. The first sensor generates a signal when, for example, a capacitance at the external surface of the housing of the computing device changes (e.g., relative to a predefined limit). The change in capacitance may be indicative of the user (e.g., a hand of the user) being in physical contact with the external surface of the housing of the computing device.

If the processor determines the user is in contact with the housing, the method 800 moves to act 806. If the processor determines the user is not in contact with the housing, the method 800 moves to act 812.

In act 806, the processor deactivates an adjustable part of a thermal management device. For example, the processor may generate a signal for a motor or solenoid coils to rotate a plurality of thermally conductive cylinders to a deactivated state, as described above with reference to FIGS. 3-5, or the processor may generate a signal to cut off a portion of a phase change device (e.g., by removing or reducing a height of an active pin), as described above with reference to FIGS. 6 and 7. When the processor deactivates the adjustable part of the thermal management device, the adjustable part may act as an insulator compared to the other part of the thermal management device. When the adjustable part is deactivated, the adjustable part may redirect heat flowing from a heat generating component (e.g., the processor) to, for example, the back of the computing device.

In act 808, the processor activates a second sensor. The second sensor identifies a temperature at the housing of the computing device. For example, the second sensor is positioned at the external surface of the housing of the computing device (e.g., the back or chassis of the computing device). The second sensor may be positioned at an expected position of a hot spot on the external surface of the housing and/or at an expected location of the hand of the user. In one example, a plurality of second sensors are spread out over the external surface of the housing of the computing device (e.g., evenly in a grid), and the processor activates all sensors of the plurality of sensors in act 808.

In act 810, the processor runs the computing device based on a sensor ranking method. A power to the computing device is controlled based on feedback from a number of temperature sensors, including the activated second sensor. The power to the computing device (e.g., a processing speed of the processor) is controlled such that temperatures measured by the temperature sensors do not exceed predetermined thresholds, respectively. The temperature sensors may include temperature sensors at the processor (e.g., the central processing unit (CPU)), a graphics processing unit (GPU), memory, a power supply, locations on a PCB of the computing device, other components or locations within the computing device, or any combination thereof, respectively.

Table 1 illustrates an exemplary control algorithm in which power to the computing device is controlled based on temperature measurements at the top of the computing device, the bottom of the computing device (e.g., with second sensors), the CPU, and the GPU.

TABLE 1
User in contact

| | | Temp | Margin/Gap to |
|---|---|---|---|
| Sensor location | Temp (C.) | Specification (C.) | Spec (C.) |
| Top sensor | 45 | 45 | 3 |
| CPU Sensor | 80 | 95 | 15 |
| GPU Sensor | 80 | 90 | 10 |
| Rear sensor | 48 | 48 | 0 |

| | |
|---|---|
| Total system power (W) | 5 (due to rear sensor hits limit) |

In the example illustrated in Table 1, the total system power for the computing device is limited to 5 W due to the measured temperature at the bottom of the computing device reaching the predetermined limit corresponding to the rear (e.g., the back) of the computing device. Additional, fewer, and/or different sensors may be used to control the power to the computing device, and different predetermined limits may be used.

In act 812, the processor activates the adjustable part of the thermal management device. For example, the processor may generate a signal for a motor or solenoid coils to rotate the plurality of thermally conductive cylinders from the deactivated state to an activated state, as described above with reference to FIGS. 3-5, or the processor may generate a signal to reintegrate the portion of the phase change device by re-introducing the active pins, as described above with reference to FIGS. 6 and 7. When the processor activates the adjustable part of the thermal management device, the adjustable part may act as a thermal conductor. When the adjustable part is activated, heat flowing from the heat generating component to, for example, the back of the computing device flows through the adjustable part.

In act 814, the processor deactivates the second sensor, and the method moves to act 810. In act 810, the power to the computing device is controlled based on feedback from a number of temperature sensors, but not including the deactivated second sensor. The power to the computing device (e.g., the processing speed of the processor) is controlled such that temperatures measured by the temperature sensors do not exceed predetermined thresholds, respectively.

Table 2 illustrates an exemplary control algorithm in which power to the computing device is controlled based on temperature measurements at the top of the computing device, the bottom of the computing device (e.g., with second sensors), the CPU, and the GPU.

TABLE 2
User not in contact

| Sensor location | Temp | Specification | Margin |
|---|---|---|---|
| Top sensor | 48 | 48 | 0 |
| CPU Sensor | 90 | 95 | 5 |
| GPU Sensor | 86 | 90 | 4 |
| Rear sensor | N/A | 48 | #VALUE! |

| | |
|---|---|
| Total system power (W) | 6 (rear sensor no longer limiter) |

In the example illustrated in Table 2, the total system power for the computing device is limited to 6 W due to the measured temperature at the top of the computing device reaching the predetermined limit corresponding to the top of the computing device. The temperature at the back of the computing device is not used as part of the control of the power to the computing device. Additional, fewer, and/or different sensors may be used to control the power to the computing device, and different predetermined limits may be used.

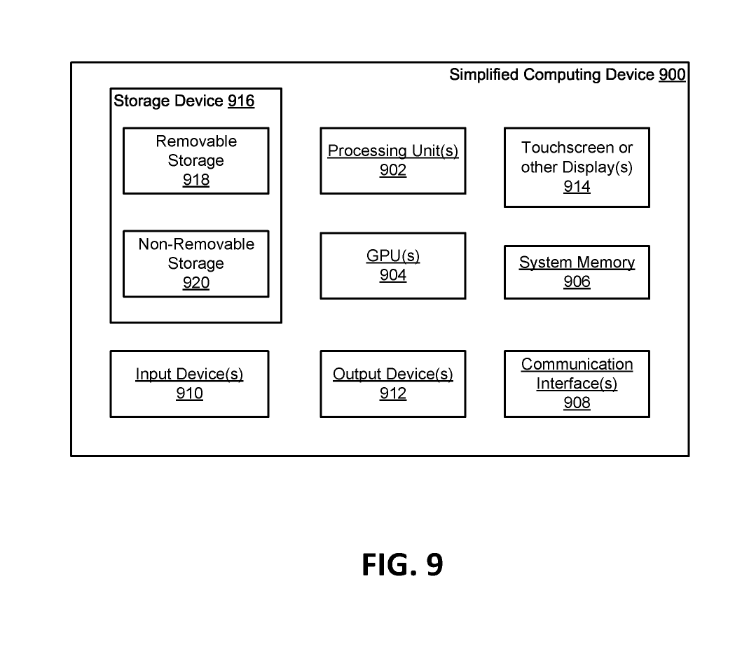

With reference to FIG. 9, a thermal management system, as described above, may be incorporated within an exemplary computing environment 900. The computing environment 900 may correspond with one of a wide variety of computing devices, including, but not limited to, personal computers (PCs), server computers, tablet and other handheld computing devices, laptop or mobile computers, communications devices such as mobile phones, multiprocessor systems, microprocessor-based systems, set top boxes, programmable consumer electronics, network PCs, minicomputers, mainframe computers, or audio or video media players. For example, the heat dissipating apparatus is incorporated within a computing environment having an active cooling source (e.g., fan).

The computing environment 900 has sufficient computational capability and system memory to enable basic computational operations. In this example, the computing environment 900 includes one or more processing units 902, which may be individually or collectively referred to herein as a processor. The computing environment 900 may also include one or more graphics processing units (GPUs) 904. The processor 902 and/or the GPU 904 may include integrated memory and/or be in communication with system memory 906. The processor 902 and/or the GPU 904 may be a specialized microprocessor, such as a digital signal processor (DSP), a very long instruction word (VLIW) processor, or other microcontroller, or may be a general purpose central processing unit (CPU) having one or more processing cores. The processor 902, the GPU 904, the system memory 906, and/or any other components of the computing environment 900 may be packaged or otherwise integrated as a system on a chip (SoC), application-specific integrated circuit (ASIC), or other integrated circuit or system.

The computing environment 900 may also include other components, such as, for example, a communications interface 908. One or more computer input devices 910 (e.g., pointing devices, keyboards, audio input devices, video input devices, haptic input devices, or devices for receiving wired or wireless data transmissions) may be provided. The input devices 910 may include one or more touch-sensitive surfaces, such as track pads. Various output devices 912, including touchscreen or touch-sensitive display(s) 914, may also be provided. The output devices 912 may include a variety of different audio output devices, video output devices, and/or devices for transmitting wired or wireless data transmissions.

The computing environment 900 may also include a variety of computer readable media for storage of information such as computer-readable or computer-executable instructions, data structures, program modules, or other data. Computer readable media may be any available media accessible via storage devices 916 and includes both volatile and nonvolatile media, whether in removable storage 918 and/or non-removable storage 920. Computer readable media may include computer storage media and communication media. Computer storage media may include both volatile and nonvolatile, removable and non-removable media implemented in any method or technology for storage of information such as computer readable instructions, data structures, program modules or other data. Computer storage media includes, but is not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other medium which may be used to store the desired information and which may accessed by the processing units of the computing environment 900.

While the present claim scope has been described with reference to specific examples, which are intended to be illustrative only and not to be limiting of the claim scope, it will be apparent to those of ordinary skill in the art that changes, additions and/or deletions may be made to the disclosed embodiments without departing from the spirit and scope of the claims.

The foregoing description is given for clearness of understanding only, and no unnecessary limitations should be understood therefrom, as modifications within the scope of the claims may be apparent to those having ordinary skill in the art.

In a first embodiment, a computing device includes a housing, an electronic component supported by the housing, and a heat spreader physically connected to the electronic component. The heat spreader includes an adjustable part that is adjustable between a first state and a second state. Heat generated by the electronic component flows through the adjustable part when the adjustable part is in the first state. The adjustable part is operable to redirect at least a portion of the heat when the adjustable part is in the second state.

In a second embodiment, with reference to the first embodiment, the heat spreader includes a first layer and a second layer. The first layer is a solid piece of material, and the second layer includes the adjustable part. The second layer is attached to the first layer. The first layer is closer to the heat generating component than the second layer. The second layer is closer to the housing than the first layer.

In a third embodiment, with reference to the second embodiment, the computing device further includes a printed circuit board (PCB) supported by the housing. The PCB has a first side and a second side opposite the first side. The first side of the PCB supports the heat generating component. The first layer of the heat spreader is attached to the second side of the PCB.

In a fourth embodiment, with reference to the second embodiment, the second layer has a first side and a second side opposite the first side. The first side of the second layer is attached to the first layer. The adjustable part is in a first orientation relative to the second layer when the adjustable part is in the first state, and the adjustable part is in a second orientation relative to the second layer when the adjustable part is in the second state. The adjustable part has a first thermal conductivity in a direction perpendicular to the first side of the second layer when the adjustable part is in the first orientation relative to the second layer and has a second thermal conductivity in the direction perpendicular to the first side of the second layer when the adjustable part is in the second orientation relative to the second layer. The first thermal conductivity is greater than the second thermal conductivity.

In a fifth embodiment, with reference to the fourth embodiment, the adjustable part includes a plurality of cylinders. The plurality of cylinders are rotatable between the first state and the second state.

In a sixth embodiment, with reference to the fifth embodiment, the plurality of cylinders are made of graphite.

In a seventh embodiment, with reference to the first embodiment, the computing device further includes a sensor operable to identify when a user is in contact with a portion of the housing. The electronic component or another electronic component within or outside of the computing device is configured to adjust the adjustable part from the first state to the second state when the sensor identifies that the user is in contact with the portion of the housing.

In an eighth embodiment, with reference to the seventh embodiment, the portion of the housing is opposite the adjustable part.

In a ninth embodiment, with reference to the seventh embodiment, the computing device further includes the other electronic component. The other electronic component includes a motor configured to rotate the adjustable part from the first state to the second state when the sensor identifies that the user is in contact with the portion of the housing.

In a tenth embodiment, with reference to the first embodiment, the adjustable part is adjustable from the first state to the second state in response to a magnetic field generated within or outside of the computing device.

In an eleventh embodiment, with reference to the first embodiment, the heat spreader is a phase change device. The phase change device has a plurality of wick structures. At least one wick structure of the plurality of wick structures is at least partially blocked when the adjustable part is in the second state.

In a twelfth embodiment, with reference to the eleventh embodiment, the at least one wick structure includes a plurality of pins. The adjustable part includes at least one pin of the plurality of pins. The at least one pin is retractable such that the first state of the adjustable part is an extended state of the at least one pin and the second state of the adjustable part is a retracted state of the at least one pin. The at least one pin is operable to block fluid flow from at least a portion of the at least one wick structure when the at least one pin is in the retracted state.

In a thirteenth embodiment, with reference to the first embodiment, the phase change device includes a heat pipe, a vapor chamber, or a combination thereof.

In a fourteenth embodiment, a thermal management device includes a first layer made of a solid piece of a first material. The first layer has a first side and a second side opposite the first side. The thermal management device further includes a second layer that is attached to the second side of the first layer. The second layer includes an adjustable part that is adjustable between a first position relative to the second layer and a second position relative to the second layer. The adjustable part is made of a second material. The adjustable part has a first thermal conductivity in a direction perpendicular to the second side of the first layer when the adjustable part is in the first position relative to the second layer and has a second thermal conductivity in the direction perpendicular to the second side of the first layer when the adjustable part is in the second position relative to the second layer. The first thermal conductivity is greater than the second thermal conductivity.

In a fifteenth embodiment, with reference to the fourteenth embodiment, the first material and the second material are a same material.

In a sixteenth embodiment, with reference to the fourteenth embodiment, the first material and the second material are different materials.

In a seventeenth embodiment, with reference to the fourteenth embodiment, the adjustable part is adjustable from the first position relative to the second layer to the second position relative to the second layer in response to a magnetic field.

In an eighteenth embodiment, a computing device includes a housing having an inner surface and an outer surface opposite the inner surface. The computing device further includes an electronic component supported by the housing, a first sensor in communication with the electronic component, a second sensor that is in communication with the electronic component, and a thermal management device that is physically connected to the electronic component. The first sensor is operable to determine whether a user is in physical contact with a first portion of the outer surface of the housing. The second sensor is operable to determine a temperature at a second portion of the outer surface of the housing. The thermal management device includes an adjustable part. The adjustable part is adjustable between a first state and a second state, and is opposite the inner surface of the housing. Heat generated by the electronic component flows through the adjustable part when the adjustable part is in the first state, and the adjustable part is operable to redirect at least a portion of the heat when the adjustable part is in the second state. When the first sensor determines the user is in physical contact with the first portion of the outer surface of the housing, the electronic component is configured to move the adjustable part from the first state to the second state, and is configured to adjust a processing speed of the electronic component based on the temperature determined by the second sensor.

In a nineteenth embodiment, with reference to the eighteenth embodiment, when the first sensor determines the user is no longer is physical contact with the first portion of the outer surface of the housing, the electronic component is configured to move the adjustable part from the second state to the first state, and is configured to adjust a processing speed of the electronic component without the temperature determined by the second sensor.

In a twentieth embodiment, with reference the eighteenth embodiment, the electronic component is a first electronic component, and the adjustable part is a first adjustable part. The computing device further includes a second electronic component supported by the housing. The thermal management device further includes a second adjustable part. The second adjustable part is opposite the inner surface of the housing. The first electronic component, the second electronic component, or a third electronic component of the computing device is configured to move the first adjustable part from the first state to the second state, in response to the first electronic component turning on, and is configured to move the second adjustable part from the first state to the second state, in response to the second electronic component turning on.

In connection with any one of the aforementioned embodiments, the computing device or the thermal management device may alternatively or additionally include any combination of one or more of the previous embodiments.

The foregoing description is given for clearness of understanding only, and no unnecessary limitations should be understood therefrom, as modifications within the scope of the claims may be apparent to those having ordinary skill in the art.

1. A computing device comprising:
a housing;
an electronic component supported by the housing; and
a heat spreader physically connected to the electronic component, the heat spreader comprising an adjustable part that is adjustable between a first state and a second state,
wherein heat generated by the electronic component flows through the adjustable part when the adjustable part is in the first state, and the adjustable part is operable to redirect at least a portion of the heat when the adjustable part is in the second state.

2. The computing device of claim 1, wherein the heat spreader comprises a first layer and a second layer, the first layer being a solid piece of material and the second layer including the adjustable part, and
wherein the second layer is attached to the first layer, the first layer being closer to the heat generating component than the second layer, the second layer being closer to the housing than the first layer.

3. The computing device of claim 2, further comprising a printed circuit board (PCB) supported by the housing, the PCB having a first side and a second side opposite the first side,
wherein the first side of the PCB supports the heat generating component, and
wherein the first layer of the heat spreader is attached to the second side of the PCB.

4. The computing device of claim 2, wherein the second layer has a first side and a second side opposite the first side, the first side of the second layer being attached to the first layer,
wherein the adjustable part is in a first orientation relative to the second layer when the adjustable part is in the first state, and the adjustable part is in a second orientation relative to the second layer when the adjustable part is in the second state, and
wherein the adjustable part has a first thermal conductivity in a direction perpendicular to the first side of the second layer when the adjustable part is in the first orientation relative to the second layer and has a second thermal conductivity in the direction perpendicular to the first side of the second layer when the adjustable part is in the second orientation relative to the second layer, the first thermal conductivity being greater than the second thermal conductivity.

5. The computing device of claim 4, wherein the adjustable part comprises a plurality of cylinders, the plurality of cylinders being rotatable between the first state and the second state.

6. The computing device of claim 5, wherein the plurality of cylinders are made of graphite.

7. The computing device of claim 1, further comprising a sensor operable to identify when a user is in contact with a portion of the housing,
wherein the electronic component or another electronic component within or outside of the computing device is configured to adjust the adjustable part from the first state to the second state when the sensor identifies that the user is in contact with the portion of the housing.

8. The computing device of claim 7, wherein the portion of the housing is opposite the adjustable part.

9. The computing device of claim 7, further comprising the other electronic component, the other electronic component comprising a motor configured to rotate the adjustable part from the first state to the second state when the sensor identifies that the user is in contact with the portion of the housing.

10. The computing device of claim 1, wherein the adjustable part is adjustable from the first state to the second state in response to a magnetic field generated within or outside of the computing device.

11. The computing device of claim 1, wherein the heat spreader is a phase change device, the phase change device having a plurality of wick structures, and
wherein at least one wick structure of the plurality of wick structures is at least partially blocked when the adjustable part is in the second state.

12. The computing device of claim 11, wherein the at least one wick structure comprises a plurality of pins,
wherein the adjustable part comprises at least one pin of the plurality of pins,
wherein the at least one pin is retractable such that the first state of the adjustable part is an extended state of the at least one pin and the second state of the adjustable part is a retracted state of the at least one pin,
wherein the at least one pin is operable to block fluid flow from at least a portion of the at least one wick structure when the at least one pin is in the retracted state.

13. The computing device of claim 1, wherein the phase change device comprises a heat pipe, a vapor chamber, or a combination thereof.

14. A thermal management device comprising:
a first layer made of a solid piece of a first material, the first layer having a first side and a second side opposite the first side; and
a second layer that is attached to the second side of the first layer, the second layer comprising an adjustable part that is adjustable between a first position relative to the second layer and a second position relative to the second layer, the adjustable part being made of a second material,
wherein the adjustable part has a first thermal conductivity in a direction perpendicular to the second side of the first layer when the adjustable part is in the first position relative to the second layer and has a second thermal conductivity in the direction perpendicular to the second side of the first layer when the adjustable part is in the second position relative to the second layer, the first thermal conductivity being greater than the second thermal conductivity.

15. The thermal management device of claim 14, wherein the first material and the second material are a same material.

16. The thermal management device of claim 14, wherein the first material and the second material are different materials.

17. The thermal management device of claim 14, wherein the adjustable part is adjustable from the first position relative to the second layer to the second position relative to the second layer in response to a magnetic field.

18. A computing device comprising:
a housing having an inner surface and an outer surface opposite the inner surface;
an electronic component supported by the housing;
a first sensor in communication with the electronic component, the first sensor being operable to determine whether a user is in physical contact with a first portion of the outer surface of the housing;
a second sensor in communication with the electronic component, the second sensor being operable to determine a temperature at a second portion of the outer surface of the housing;
a thermal management device that is physically connected to the electronic component, the thermal management device comprising an adjustable part, the adjustable part being adjustable between a first state and a second state and being opposite the inner surface of the housing,
wherein heat generated by the electronic component flows through the adjustable part when the adjustable part is in the first state, and the adjustable part is operable to redirect at least a portion of the heat when the adjustable part is in the second state, and
wherein when the first sensor determines the user is in physical contact with the first portion of the outer surface of the housing, the electronic component is configured to move the adjustable part from the first state to the second state, and is configured to adjust a processing speed of the electronic component based on the temperature determined by the second sensor.

19. The computing device of claim 18, wherein when the first sensor determines the user is no longer in physical contact with the first portion of the outer surface of the housing, the electronic component is configured to move the adjustable part from the second state to the first state, and is configured to adjust a processing speed of the electronic component without the temperature determined by the second sensor.

20. The computing device of claim 18, wherein the electronic component is a first electronic component and the adjustable part is a first adjustable part,
wherein the computing device further comprises a second electronic component supported by the housing,
wherein the thermal management device further comprises a second adjustable part, the second adjustable part being opposite the inner surface of the housing, and
wherein the first electronic component, the second electronic component, or a third electronic component of the computing device is configured to move the first adjustable part from the first state to the second state, in response to the first electronic component turning on, and is configured to move the second adjustable part from the first state to the second state, in response to the second electronic component turning on.
